(19) United States
(12) Patent Application Publication
(10) Pub. No.: US 2015/0136985 A1
(43) Pub. Date: May 21, 2015

(54) INFRARED SENSOR WITH LIMITATION APERTURE

(71) Applicant: Melexis Technologies NV, Tessenderlo (BE)

(72) Inventor: Luc BUYDENS, Kasterlee (BE)

(21) Appl. No.: 14/542,745

(22) Filed: Nov. 17, 2014

(30) Foreign Application Priority Data
Nov. 18, 2013 (GB) 1320284.1

(51) Int. Cl. H01L 31/0232; H01L 31/0352; G01J 5/02

(52) U.S. Cl. CPC H01L 31/0232; G01J 5/0265; H01L 31/0352
USPC 250/338.4

(57) ABSTRACT

A semiconductor device comprising an infrared sensor assembly for sensing infrared radiation is described. The infrared sensor assembly comprises a single sensing element for sensing infrared radiation and an aperture means comprising a plurality of apertures. The sensing element and the aperture means thereby are positioned with respect to each other so that the plurality of apertures are positioned in front of the same, single sensing element so that the plurality of apertures limit the field of view of the same, single sensing element for impinging radiation.

### FIELD OF THE INVENTION

The invention relates to the field of infrared sensors. More specifically it relates to methods and systems for infrared sensing with a small field of view.

### BACKGROUND OF THE INVENTION

In a large number of applications, stringent requirements are posed on infrared sensors: sensors typically should be compact, have high sensitivity and have good directionality, i.e. a limited field of view (FOV). The easiest way to reduce the FOV of a sensor is by introducing an aperture between the radiation source and the sensing element of the sensor. The size of the aperture as well as the distance between the aperture and the sensing element directly influences the impact on the field of view of the sensor. The smaller the size of the aperture and the larger the distance between the aperture and the sensing element, the better the field of view is reduced. Nevertheless, a large distance between the aperture and the sensing element results in a bulky sensor assembly and a small aperture size typically results in a low sensitivity of the detector. Such solutions typically therefore are not preferred in a number of applications, such as for example mobile digital devices, where packaging of the sensor assembly should be flat. The same problem occurs when implementing an alternative technique for limiting the field of view, i.e. when applying lens systems, as this also results in a large increase of the height of the sensor.

Another parameter to take into account is the size of the sensing element itself. Obviously, the packaging of a sensor assembly will be reduced with a reduced sensing element, but the sensitivity of the sensor is also significantly reduced.

U.S. Pat. No. 3,963,926 illustrates an alternative class of infrared sensors, whereby use is made of a plurality of sensing elements, e.g. a sensor array. A plurality of sensing elements are connected forming a detector array, for instance a plurality of thermopiles connected in series, and the field of view for each of the sensing elements is reduced by the application of individual apertures. Such apertures reduce the field of view, while increasing only slightly the thickness of the sensor. Nevertheless, the quality of an infrared sensor is also determined by its thermal resistance. Using a plurality of sensors for sensing a signal does not render the same sensitivity as using a sensor with a larger sensing surface, as thermal losses occurring in a sensor array are substantially higher than those when using a sensor with a larger sensing surface. This renders solutions of multiple pixel sensors not attractive for the sensing applications envisaged, e.g. mobile device applications.

### SUMMARY OF THE INVENTION

It is an object of embodiments of the present invention to provide an integrated circuit comprising an infrared sensor assembly having a small packaging size with a limited thickness (small optical path length) while having good sensing properties.

It is an advantage of embodiments of the present invention that integrated circuits comprising an infrared sensor assembly are obtained having a good sensitivity with a limited field of view.

It is an advantage of embodiments of the present invention that integrated circuits comprising an infrared sensor assembly are obtained having a good thermal resistance, resulting in accurate sensing.

It is an advantage of embodiments of the present invention that integrated circuits comprising an infrared sensor assembly are obtained combining compactness with a good directionality—i.e. limited field of view—and good sensitivity.

The above objective is accomplished by a method and device according to the present invention.

The present invention relates to an integrated circuit comprising an infrared sensor assembly for sensing infrared radiation, the infrared sensor assembly comprising a single sensing element for sensing infrared radiation and an aperture means comprising a plurality of apertures, the sensing element and the aperture means being positioned with respect to each other so that the plurality of apertures are positioned in front of the same, single sensing element so that the plurality of apertures limit the field of view of the same, single sensing element for impinging radiation.

It is an advantage of embodiments of the present invention that a good field of view is obtained, for example significantly better than at least some prior art devices where no aperture is used, or where only a single aperture is used. It is an advantage of embodiments of the present invention that the limited field of view is obtained without jeopardizing too much the impinging radiation. It is an additional advantage of embodiments of the present invention that the packaging size, especially the package thickness (also referred to as “height”) of the infrared sensor assembly, is not increased too much with respect of a sensor without aperture means.

The aperture means may have a thickness so that the plurality of apertures have inner walls, the inner walls of the apertures being substantially non-reflecting. It is an advantage of embodiments of the present invention that the reduction of the field of view is further enhanced by avoiding reflection of radiation impinging under large angles.

The aperture means may have a thickness and the inner walls and/or aperture means comprising an absorbing material so as to absorb radiation being impinging thereon. It is an advantage of embodiments of the present invention that radiation impinging on an inner wall of an aperture cannot travel to a neighbouring aperture, as this would be negatively influencing the field of view reduction.

The absorbing material may comprise or consist of silicon doped with at least one dopant selected from the group consisting of Al, Au, As, B, and P, for example with a concentration of at least 10¹⁸/cm³. It is an advantage that such a material has a high absorption for infrared energy, and that it can be easily produced, e.g. by using lithography and etching techniques.

The aperture means may furthermore have a radiation receiving side, whereby the surface of the radiation receiving side comprises aperture openings for the plurality of apertures and radiation blocking elements.

The radiation blocking elements may be any of reflective elements or absorbing elements.

The aperture means may be a perforated plate, e.g. a perforated micro-plate, e.g. a semiconductor substrate having a plurality of perforations made by etching.

The aperture means may comprise a plurality of apertures having any of a tubular shape, a circular cross-section, a quadrangular cross-section, a rectangular cross-section or an oval cross-section.

The plurality of apertures may be tubular openings having a ratio of cross sectional distance (e.g. diameter in case of circular or elliptical opening, or diagonal in case of a square or rectangular opening) over length (of the tubular opening) in the range of 0.05 to 0.30.

The plurality of apertures may be tubular openings having a ratio of diameter or diagonal over length (of the tubular opening) in the range of 0.05 to 0.10.

The plurality of apertures may be tubular openings having a length in the range of 200 μm to 500 μm or 300 μm to 500 μm, and a diameter or diagonal in the range of 50 μm to 100 μm. It is an advantage of such apertures that they provide a very small FOV, yet require only a very small height. By providing a plurality of such aperatures arranged over the same (single) sensor, the total energy and thus the sensitivity can be dramatically increased.

The distribution and/or the size and/or the shape of the apertures may be determined as function of the application envisaged.

It is an advantage of embodiments of the present invention that the circuitry does not substantially increase packaging size.

The aperture means may comprise a plurality of apertures of a size lower than half millimeter (500 micron). It is an advantage of embodiments of the present invention that the field of view can be easily made lower than 60°, for example equal to about 40°.

The distance between the aperture stop surface for receiving radiation and the sensing element may be lower than 300 μm.

The invention is also related to the integrated circuit described above, packaged in a sensor assembly package of a height lower than 1.5 mm. It is an advantage of embodiments of the present invention that the sensor is suitable for mobile applications, e.g. portable or hand-held applications such as mobile phones.

It is an advantage of embodiments of the present invention that an integrated circuit comprising a temperature sensor assembly is obtained that has a limited field of view and a high sensitivity.

It is an advantage of embodiments of the present invention that the thickness of the sensor can be limited, resulting in the possibility of using the integrated circuit comprising the temperature sensor assembly in mobile devices. It thereby is an advantage that a large sensor width can be obtained, as well as that a good field of view can be obtained with a relatively thin thickness.

The present invention also relates to the use of the integrated circuit described above as a temperature sensor with a limited field of view.

The present invention also relates to the use of a packaged temperature sensor assembly as described above.

Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### BRIEF DESCRIPTION OF THE DRAWINGS

FIG. 1 illustrates a cross-section view of an infrared sensor assembly having a sensing element and an aperture means comprising a plurality of apertures whose projection is limited within the area of the sensing element, according to an embodiment of the present invention.

FIG. 2 illustrates a top view of an aperture means comprising a plurality of circular apertures in a triangular distribution, according to an embodiment of the present invention.

FIG. 3 illustrates a top view of an aperture means comprising a plurality of rectangular apertures, according to an embodiment of the present invention.

The drawings are only schematic and are non-limiting. In the drawings, the size of some of the elements may be exaggerated and not drawn on scale for illustrative purposes.

Any reference signs in the claims shall not be construed as limiting the scope.

In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Where in embodiments of the present invention reference is made to “sensing element”, reference is made to a device able to receive radiation of a certain wavelength or wavelength range, for example infrared radiation having a wavelength in the range of about 700 nm to about 20 μm, and produce a signal in response to the reception. This signal can be an electrical signal, for instance. Particular examples of sensing elements will be enumerated as embodiments of the present invention.

Where in embodiments of the present invention reference is made to “aperture means”, reference is made to a means for partially blocking radiation and partially transmitting radiation, the aperture resulting in radiation within a specific angle being transmitted and other radiation being blocked. According to the present invention the aperture means comprises a plurality of apertures. The aperture means may be a set of diaphragms, or more generally, a perforated or, in general, holed sheet of material, the material chosen according to its opacity for a certain range of radiation wavelength. For incident radiation characterized by a wavelength within the selected range, the radiation will be allowed to pass only through the plurality of holes or apertures. Different embodiments of the present invention comprise a plurality of apertures produced in the aperture means, limiting the amount of light reaching the sensing element. The main purpose of the aperture means is to restrict the field of view by restricting the optical path via which radiation, in particular infrared light, originating from an object can reach the sensing element.

Where in embodiments of the present invention reference is made to “sensor assembly”, reference is made to a sensing element and an aperture means placed between the sensing element and any source of radiation or incident radiation, so the allowed angles of incident radiation are limited, effectively limiting the FOV of the sensing element.

In a first aspect, the present invention relates to an integrated circuit comprising an infrared sensor assembly for sensing infrared radiation. The infrared sensor assembly thereby comprises a single sensing element for sensing infrared radiation and an aperture means comprising a plurality of apertures. The sensing element and the aperture means thereby are positioned with respect to each other so that the plurality of apertures are positioned in front of the same, single sensing element so that the plurality of apertures limit the field of view of the same, single sensing element for impinging radiation.

The integrated circuit may comprise a plurality of such sensor assemblies, whereby each sensor assembly has a single sensing element and an aperture means with a plurality of apertures arranged for allowing IR radiation to pass to said single sensing element.

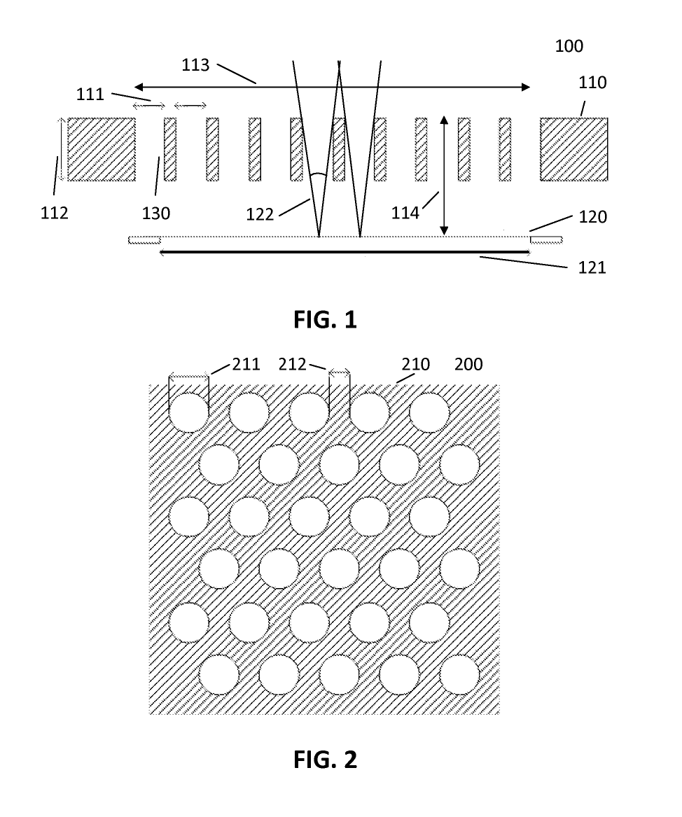

By way of illustration, embodiments of the present invention not being limited thereto, an exemplary sensor assembly according to an embodiment of the present invention is further described with reference to FIG. 1 to FIG. 3, illustrating standard and optional features.

The sensor assembly 100 shown in FIG. 1 according to embodiments of the present invention comprises a unique and individual sensing element 120 with sensing area 121, totally or partially covered by an aperture means 110. Such sensor assembly may advantageously be an infrared sensor assembly. The aperture means 110, which advantageously can be introduced for protecting the sensing element 120, comprises a plurality of apertures 111 and has a predefined thickness 112, e.g. in the range of 200 μm to 500 μm or 300 μm to 500 μm. The aperture means advantageously may be based on a flat film or plate, for example may be based on a metal plate or polymeric flat sheet, or based on a semiconductor substrate. The plurality of apertures 111 may be microfabricated, milled, punched, pierced, etched, laser ablated, etc. or are generally produced in the aperture means material. The apertures may for example be produced by generating holes or pipes through the thickness of a sheet like material. Typically, the apertures may be created perpendicular to the plate surface, although embodiments of the present invention are not limited thereto. The apertures alternatively may for example form slant tunnels through the thickness of the aperture means. The surface of the aperture means suitable for receiving incident radiation is at a certain distance 114 to the detector 120. The combination of an appropriate distance 114 and the aperture size 111 effectively can reduce the FOV 122 in every point of the sensing area in the sensing element 120. The sensing element and the aperture means thereby are positioned with respect to each other so that the plurality of apertures are positioned in front of the same, single sensing element. This results in the projections of the apertures advantageously being limited within the sensing area 121 of the sensing element 120. It thereby is advantageous that effectively as much as possible of the sensing area 121 is used. Advantageously, absorbent elements are introduced in or on the inner walls of the aperture defined by the aperture means thickness 112 and each aperture 111 therein. In a preferred embodiment the surfaces of the inner walls 130 of each aperture are made anti-reflective, e.g. coated with a radiation-absorbent substance or made absorbent in a different way in order to avoid reflections in the wall (which would reduce the effect of the aperture on the FOV). In a particular embodiment of the present invention, the aperture means comprises or is made of an absorbing material. Particularly suited is silicon doped with at least one dopant selected from the group consisting of Al, Au, As, B, and P, in a concentration of at least 10¹⁸/cm³.

The average diameter of the cross-section of the aperture (parallel with the receiving plane) for the individual apertures may be any suitable size, e.g. between 10 μm and 100 μm, such as for example between 30 μm and 80 μm, or for example in the range of 50 μm to 100 μm, such as for example about 50 μm.

According to embodiments of the present invention, radiation blocking elements may be comprised in the surface of the aperture means suitable for receiving incident radiation, advantageously reducing or avoiding crosstalk between the apertures and an undesirable increase of FOV. These blocking elements may comprise absorbing elements, reflective elements or a combination thereof.

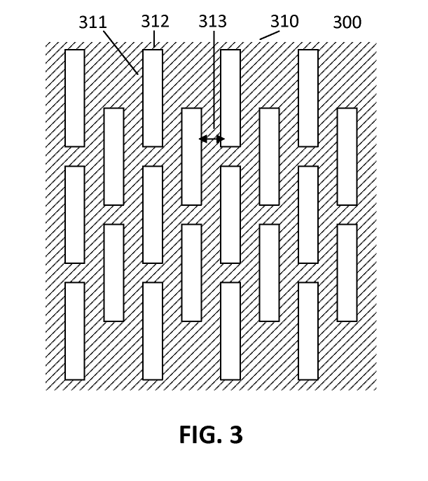

The distribution of the apertures in the aperture stop is discussed in FIGS. 2 and 3.

FIG. 2 represents a frontal view of the aperture means 210 of sensor assembly 200, which is the surface exposed to radiation. The apertures 111 may take several shapes and in the case represented in FIG. 2, the shapes are circular as cylindrical tubes 130 are used as apertures in the aperture means. Different embodiments of aperture means are defined by the shape of the apertures and also by their distribution. The case represented in FIG. 2 shows an aperture stop defined by circular apertures with a diameter 211 and a distribution with triangular symmetry, with a separation 212 between apertures. This separation 212 between apertures must be optimized taking into account an effective limitation of FOV and protection of the sensing element, and an effective utilization of the sensing area 121 defined by the sensing element 120. The combination of the relative sizes of apertures and separations between them defines the relative amount of radiation that reaches the sensor surface with respect to the amount of radiation being impinging on the sensor assembly, which in embodiments of the present invention, may be higher than 50%, for instance equal to about 60%.

In particular embodiments, the length of the tubular opening is relatively large with respect to the diameter. For example, the tubular openings may have an aspect ratio, e.g. ratio of diameter 211 over tubular length 112, in the range of 0.05 to 0.30, or in the range of 0.05 to 0.10.

In particular embodiments, the tubular openings have a length in the range of 300 μm to 500 μm and a diameter in the range of 50 μm to 100 μm.

Of course, if the cross section was not circular but square or rectangular or diamond for example, this can be expressed as the ratio of the (longest) diagonal over the tubular length.

A rectangular aperture shape is defined in the frontal view of the aperture means 310 of the sensor assembly 300 shown in FIG. 3, suitable for applications in which a limitation of FOV is needed mainly in one direction. In this case, the FOV is heavily limited in the 312 direction, while in the 311 direction the limitation is less stringent.

In general, the shape of each aperture forming the aperture array, as well as its distribution, size and separation, are highly controllable parameters which may be tuned to satisfy the needs of different applications and geometries. The amount of radiation that the detector receives is controlled by the amount and distribution of apertures in the aperture stop For a typical application, the transmission of radiation may be higher than 50%. This has the advantage that, because the sensing element is a single device instead of a detector array, there is no sensitivity loss due to thermal resistance.

According to embodiments of the present invention, for a same sensor element a plurality of apertures is used. The sensor element can be any suitable sensor element such as for example a thermopile, solid-state photomultiplier, a bolometer, a power module, a semiconductor sensor, an integrated circuit sensor, etc. The plurality (N) of apertures limits the FOV by a certain angle A. Embodiments according to the present invention thereby have the advantage that the sensing power is higher than a corresponding device having a plurality of interconnected sensing elements N covering the same detection area and having the same FOV. The latter is caused by the thermal resistance of embodiments of the present invention being substantially better than the thermal resistance of such an alternative configuration. Embodiments of the present invention avoids electrical contacts between different sensor elements as a single sensor element can be used. Furthermore, environmental effects such as thermal loss, is smaller when a single sensor element is used compared to the situation wherein a plurality of elements is used covering the same area.

According to embodiments of the present invention, also multiple sensing elements may be present on the integrated circuit, but according to the present invention, each sensing element has a limited FOV due to an aperture means comprising a plurality of apertures for that sensing element.

According to embodiments of the present invention, the packaging size, more particularly the package thickness can be small, because use of a plurality of apertures requires a shorter thickness of the aperture means than would be the case for an aperture means with a single aperture. The distance of the aperture means to the sensor also can be small, which also assists in obtaining a small package thickness. The distance between the aperture means and the sensing element, which is related to the height of the assembly, can be made small enough to be suitable for mobile digital devices, like for example IR detectors for mobile phones, with no need to decrease the size of the sensing element, and still obtaining sufficient limitation of the FOV.

The total height of the packaging should be smaller than 2.0 mm, advantageously smaller than 1.5 mm, more advantageously smaller than 1.0 mm, and the FOV is preferably reduced to less than 40°.

By way of illustration, embodiments of the present invention not being limited thereto, a particular example is discussed below.

In a first example, the aperture means is a non-transparent plate of 200 μm thick and the apertures are 50 μm diameter holes, thus the aspect ratio of these aperatures is 50/200=0.25. The aperture means is positioned on top of the same sensor surface. The resulting field of view is determined by

FOV=atan(a/D),

which results for the present example in a field of view of 30°. As indicated above, the sensor surface can remain large as it does not determine the field of view. Using the aperture array, the whole sensor surface is illuminated, resulting in a good sensitivity. Furthermore, the amount of light that passes the aperture is still significantly high, also resulting in good sensitivity. By using an array of apertures, the diameter of the individual apertures can be small, making it possible to use a reduced thickness of the aperture means and resulting in a low height of the package. The present example illustrates an advantageous embodiment wherein the apertures have a round—circular—shape to have a circular FOV. As also indicated above, different shapes can be chosen to tailor the FOV to the application (example: wide FOV in 1 direction, narrow FOV in the perpendicular direction). The amount of radiation that is transmitted can be determined as follows:

$$transmission = T = \frac{π}{2 \sqrt{3} {( 1 + \frac{s}{a} )}^{2}}$$

theroretical maximum transmission is

$$\frac{π}{2 \sqrt{3}} ,$$

resulting in 91% of the radiation reaching the sensor surface. For another example where the aperture diameter is 50 μm and the distance between the apertures is 10 μm, a transmission of 63% is obtained. This shows that with such an aperture array only ⅓ of the signal is lost.

1. An integrated circuit comprising an infrared sensor assembly for sensing infrared radiation, the infrared sensor assembly comprising a single sensing element for sensing infrared radiation and an aperture means comprising a plurality of apertures, the sensing element and the aperture means being positioned with respect to each other so that the plurality of apertures are positioned in front of the same, single sensing element so that the plurality of apertures limit the field of view of the same, single sensing element for impinging radiation.

2. The integrated circuit according to claim 1, the aperture means having a thickness so that the plurality of apertures have inner walls, the inner walls of the apertures being substantially non-reflecting.

3. The integrated circuit according to claim 1, the aperture means having a thickness and the inner walls and/or aperture means comprising an absorbing material so as to absorb radiation being impinging thereon.

4. The integrated circuit according to claim 3, wherein the absorbing material comprises silicon doped with at least one dopant selected from the group consisting of Al, Au, As, B, and P, in a concentration of at least 10¹⁸/cm³.

5. The integrated circuit according to claim 1, the aperture means furthermore having a radiation receiving side, whereby the surface of the radiation receiving side comprises aperture openings for the plurality of apertures and radiation blocking elements.

6. The integrated circuit according to claim 5, wherein the radiation blocking elements are any of reflective elements or absorbing elements.

7. The integrated circuit according to claim 1, wherein the aperture means is a perforated plate.

8. The integrated circuit according claim 1, wherein the plurality of apertures have a tubular shape with a circular cross-section, a quadrangular cross-section, a rectangular cross-section or an oval cross-section.

9. The integrated circuit according to claim 1, wherein the plurality of apertures are tubular openings having an aspect ratio of cross sectional distance over length in the range of 0.05 to 0.30.

10. The integrated circuit according to claim 1, wherein the plurality of apertures are tubular openings having a ratio of diameter or diagonal over length in the range of 0.05 to 0.10.

11. The integrated circuit according to claim 1, wherein the plurality of apertures are tubular openings having a length in the range of 200 nm to 500 nm and a diameter or diagonal in the range of 50 nm to 100 nm.

12. The integrated circuit according to claim 1, wherein the distance between the aperture stop surface for receiving radiation and the sensing element is lower than 300 μm.

13. Use of the integrated circuit according to claim 1 as a temperature sensor with a limited field of view.

14. A packaged integrated circuit comprising the integrated circuit according to claim 1, the package having an external height lower than 1.5 mm.

15. Use of the packaged integrated circuit according to claim 14 as a temperature sensor in a handheld device.
